(19) United States
(12) Patent Application Publication
(10) Pub. No.: US 2022/0027702 A1
(43) Pub. Date: Jan. 27, 2022

(54) PAYMENT CARD AND METHOD FOR FABRICATING THE SAME

(71) Applicant: ICK International, Inc., BREA, CA (US)

(72) Inventor: Soo Hyang KANG, BREA, CA (US)

(21) Appl. No.: 16/938,870

(22) Filed: Jul. 24, 2020

(51) Int. Cl. G06K 19/077; H01L 23/498; H01L 23/552; H01L 23/66; H01L 21/48

(52) U.S. Cl. CPC G06K 19/07722; H01L 23/49838; H01L 23/49855; H01L 2223/6677; H01L 23/66; H01L 21/4853; G06K 19/07773; H01L 23/552

(57) ABSTRACT

A method for manufacturing a payment card which includes the steps of forming a shield layer which includes ferromagnetic material; forming an inlay wherein the inlay includes an antenna and an interior edge forming a hole; forming a metal layer which includes a recess sized to receive the shield layer; and placing the shield layer into the recess of the metal layer. The shield layer further includes an opening sized to receive an integrated circuit (“IC”) chip. The recess is formed within a boundary of the metal layer and on a first side of the metal layer, the recess including an opening through to a second side of the metal layer. The opening of the recess and the opening of the shield layer are sized to receive the IC chip, of which includes a contact area.

### FIELD OF THE INVENTION

The present invention relates to a card and a method for fabricating the card, more particularly, to a payment card and a method for fabricating the payment card capable of contact and/or contactless communication.

### BACKGROUND OF THE INVENTION

Payment cards using an integrated circuit (IC) chip or a combination of an IC chip and a magnetic strip are classified into contact types and contactless types. Contactless payment cards, e.g. contactless smart cards, can employ radio-frequency (RF) communication or near-field communication (NFC) to communicate with a compatible reader and have been used as credit cards, transportation passes, identification cards, membership cards, and the like.

While such cards are generally made substantially of plastic materials such as polyvinyl chloride (PVC), card-issuing companies have found a need to produce metal payment cards, which can feel and look more sophisticated and higher in quality due to the materials used for their manufacture. Furthermore, such metal payment cards may be more durable than their plastic counterparts. Accordingly, metal payment cards have grown in popularity in recent years; for example, credit card companies may issue metal payment cards to customers with high credit ratings or high net worth.

However, such metal payment cards have been by and large limited to contact-type metal payment cards, e.g. contact-type metal smart cards. When metal layers are incorporated into contactless-type metal payment cards, the attenuation of any kind of RF or NFC signal due to the presence of the metal layers often makes contactless metal cards unusable.

To overcome this problem, multiple solutions have been proposed. One proposed solution is to manufacture plastic contactless cards having thin metal film layers. However, such films are susceptible to deterioration or discoloration. Additionally, a plastic card having a metal thin film lacks the desirable heft of a card having substantial metal layers. Another proposed solution involves the introduction of a slit through a part of a metal sheet to allow metallic layers to have contactless communication capabilities (for example through a metallic case of a smart phone). However, when incorporated into flat cards, the incorporation of a slit is detrimental to its structural properties. Namely, a card having a slit can introduce weak structural points that are significant enough to make those areas of the card be highly susceptible to cracking and breaking. Such fragility is not desirable in metal payment cards that are frequently handled and may be subject to flexing, dropping, or other abuse. For example, a payment card having a slit may be put into a wallet and subsequently be sat on resulting in the card breaking due to torsional and normal stresses. Additionally, the manufacturing processes of these solutions may require expensive retooling of machines or fabrication of customized jigs, any of which may lead to higher costs and introduce inefficiencies in the manufacturing chain.

Therefore, there is a need for a metal payment card that is durable without suffering from the drawbacks of traditional metal cards used in contactless (as well as contact) communication during transactions. Additionally, there is a need to manufacture metal payment cards efficiently without too high of a cost. This invention is directed to address the above problems and satisfy a long-felt need.

### SUMMARY OF THE INVENTION

The present invention contrives to solve the disadvantages and shortcomings of the prior art. The present invention provides a payment card and a method for manufacturing the same.

Hereinafter, in this specification and claims, NFC and RF are not largely distinguished, but are collectively called “RF” or “contactless”, and a chip for all contactless cards including an NFC chip for the near field or an RF chip for the far field is called a “RFIC” chip.

An object of the present invention is to provide a method for manufacturing a transaction card, the method including the steps of forming a shield layer which includes ferromagnetic material; forming an inlay wherein the inlay includes an antenna and an interior edge forming a hole; forming a metal layer which includes a recess sized to receive the shield layer; and placing the shield layer into the recess of the metal layer. The shield layer further includes an opening sized to receive an integrated circuit (“IC”) chip. The recess is formed within a boundary of the metal layer and on a first side of the metal layer. The recess includes an opening through to a second side of the metal layer. The opening of the recess and the opening of the shield layer are sized to receive the IC chip, and the IC chip includes a contact area.

Another object of the present invention is to provide a payment card which includes a metal layer that includes a boundary and a recess formed within the boundary; an inlay which includes an antenna; a shield layer positioned between the inlay and the metal layer; an integrated circuit (“IC”) chip including a chip contact and a contact area, wherein the contact area contacts the antenna of the inlay; and a back sheet constructed to cover the IC chip, the inlay, the shield layer, and the metal layer. The recess is constructed to receive the shield layer, the IC chip, and the inlay; and the recess and the shield layer include holes sized to receive the IC chip. The inlay includes an interior edge forming a hole.

The advantages of the present invention are: (1) removing or reducing interference between the antenna and the metal layer; (2) methods that reduce the need for customized manufacturing equipment, thereby leading to a reduction of manufacturing costs; (3) manufacturing methods that minimize marks or other visible physical artifacts from the manufacturing process; (4) methods to use less heat for the manufacture of the payment card, thereby saving energy costs; (5) high throughput manufacturing of the payment cards; and (6) establishing a connection between the antenna and the IC chip apart from the metal layer, thereby reducing interference between the communication of the antenna and the IC chip.

Although the present invention is briefly summarized, a fuller understanding of the invention can be obtained by the following drawings, detailed description, and appended claims.

### BRIEF DESCRIPTION OF THE DRAWINGS

These and other features, aspects, and advantages of the present invention will become better understood with reference to the accompanying drawings, wherein:

FIGS. 1A and 1B respectively show top and bottom views of a payment card having an IC chip and a plurality of layers;

FIG. 2 shows an exploded perspective view of the payment card shown in FIGS. 1A-B;

FIGS. 3A and 3B respectively show top and bottom views of a metal layer of the payment card of FIGS. 1A-B;

FIG. 4 is a top view showing arrangements of individual shield layers during the manufacturing of the shield layers for the payment card of FIGS. 1A-B;

FIGS. 5A and 5B show schematical side views the shield layer;

FIGS. 6A and 6B show placement of the shield layer into the metal layer of the payment card;

FIGS. 7A to 7C show the manufacturing of the inlay of the payment card;

FIGS. 8A and 8B show placement of the inlay on top of the IC chip and the shield layer of the payment card;

FIGS. 9A and 9B show preparation of the IC chip for use with the payment card;

FIG. 10 shows a view of one of the sides of the IC chip;

FIGS. 11A-C show sectional views of the payment card shown in FIGS. 1A-B with FIG. 11A with the IC chip and FIG. 11B showing FIG. 11A without the IC chip, and FIG. 11 C showing an exploded sectional view of FIG. 11A;

FIG. 12 shows a top view of the back sheet during the manufacturing thereof;

FIG. 13 shows the steps for a method of manufacturing the payment card of FIG. 1;

FIG. 14 shows a top perspective view of a metal jig used during the manufacturing of the payment card; and

FIG. 15 shows a partial view of the metal jig of FIG. 14 used for the manufacture of the payment card.

### DETAILED DESCRIPTION OF THE EMBODIMENTS OF THE INVENTION

Reference will now be made in detail to the preferred embodiments of the present invention, examples of which are illustrated in the accompanying drawings, which form a part of this disclosure. It is to be understood that this invention is not limited to the specific devices, methods, conditions or parameters described and/or shown herein, and that the terminology used herein is for the purpose of describing particular embodiments by way of example only and is not intended to be limiting of the claimed invention.

Also, as used in the specification including the appended claims, the singular forms “a”, “an”, and “the” include the plural, and reference to a particular numerical value includes at least that particular value, unless the context clearly dictates otherwise. Ranges may be expressed herein as from “about” or “approximately” one particular value and/or to “about” or “approximately” another particular value. When such a range is expressed, another embodiment includes from the one particular value and/or to the other particular value. Similarly, when values are expressed as approximations by use of the word “about”, it will be understood that the particular value forms another embodiment.

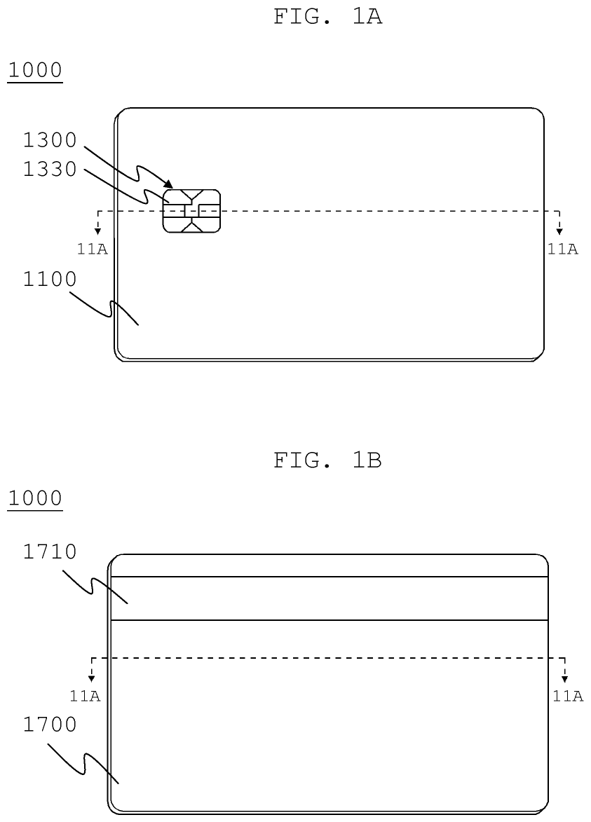

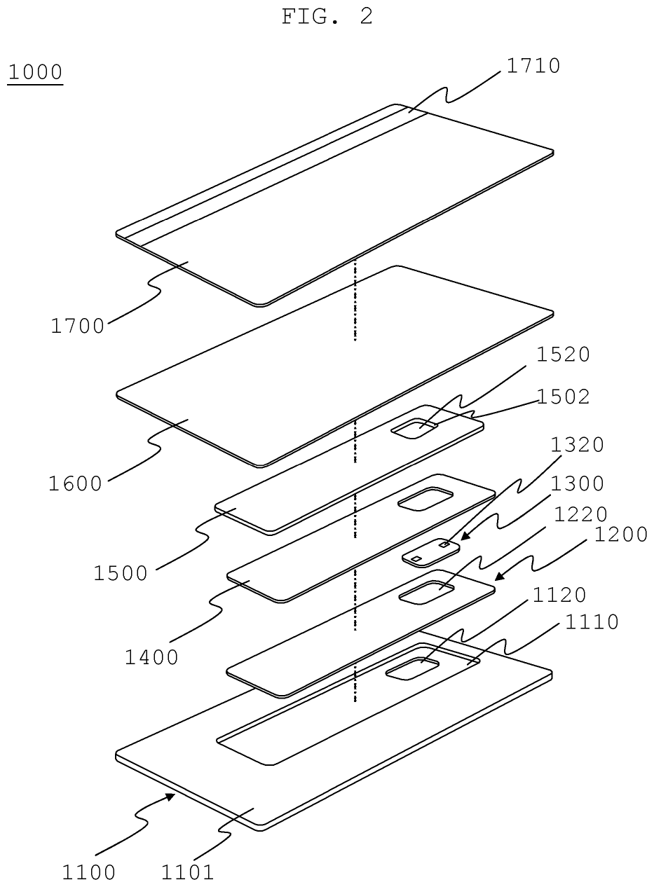

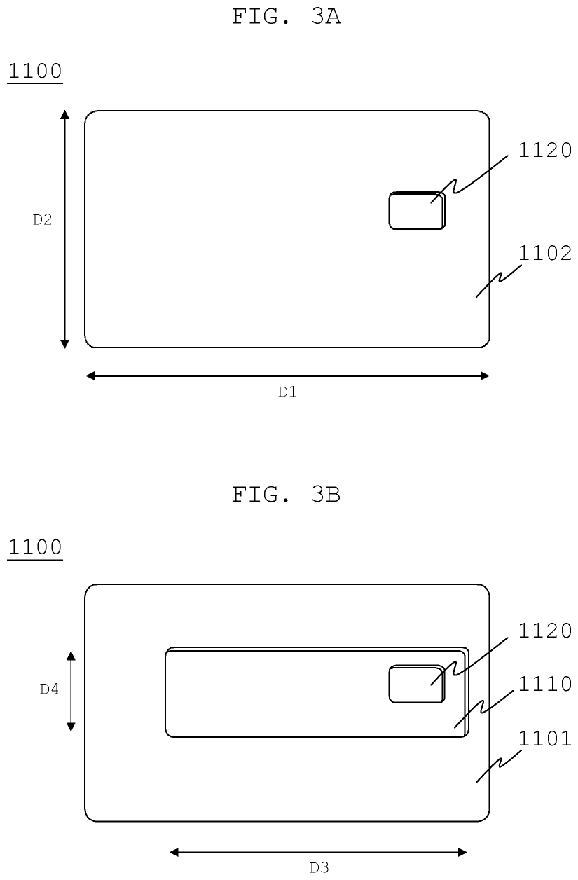

FIGS. 1 and 2 shows a payment card (1000) which includes a metal layer (1100), the metal layer (1100) including a boundary and a recess (1110) formed within the boundary; an inlay (1500) which includes an antenna (1510) (shown in FIGS. 3A-B); a shield layer (1200) positioned between the inlay (1500) and the metal layer (1100), the shield layer (1200) constructed to block electromagnetic interference to the antenna by the metal layer (1100); an IC (integrated circuit) chip (1300) including a contact area (1310) that contacts the antenna (1510) of the inlay (1500); and a back sheet (1700) constructed to cover the IC chip (1300), the inlay (1500), the shield layer (1200), and the metal layer (1100). The payment card (1000) may include smart cards, MfD cards, NFC cards, and the like that are contact and/or contactless. The recess (1110) of the metal layer (1100), as shown in FIGS. 2 and 3B, is constructed to have a depth to receive the shield layer (1200), the IC chip (1300), and the inlay (1500) therein. Furthermore, the recess (1110) and the shield layer (1200) include holes (1120, 1220) sized to receive the IC chip (1300). Additionally, the inlay (1500) includes an interior edge forming a hole (1520). While the antenna (1510) can be on both sides of the inlay (1500), the antenna (1510) is preferably located on one of the sides of the inlay (1500) and is directed towards the contact area (1310) of the IC chip (1300). Therefore, preferably, the antenna (1510) is deposited on one of the two faces of the planar inlay (1500). Furthermore, the contact area (1310) means at least one contact area (1310) in all embodiments of this invention. Preferably, there are a plurality of contact areas (1310) formed on the IC chip (1300).

FIGS. 3A and 3B show top and bottom views of the metal layer (1100) respectively. The metal layer (1100) may be made of any metal or metal alloy known in the art, e.g. stainless steel, aluminum alloys, other alloys, and the like. The metal layer (1100) is manufactured by CNC (Computerized Numerical Control) milling within a +0.01 mm tolerance rate, as manufacture of the metal layer (1100) will be difficult below this tolerance rate. The size of the metal layer (1100), in terms of length (D1) and width (D2) can be about 85.6 mm±0.3 mm and about 53.98 mm±0.3 mm respectively. As shown, a recess (1110) can be milled in the metal layer (1100). The maximum/minimum milling range, or max/min size, for the recess (1110) of the metal layer (1100), in terms of length (D3) and width (D4) of the recess (1110), is 64 mm±0.1 mm and 21 mm±0.1 mm respectively. If the milling range exceeds D3 and D4, then the large recess may result in bending of the metal layer (1100). Preferably, the minimum milling range will be used to mill the recess (1110) of the metal layer (1100) to reduce, and thus improve, manufacturing time. With respect to the milling range of the recess (1110), it is recommended that the inlay (1500) (see below) be tested to decide the amount of inlay turns needed.

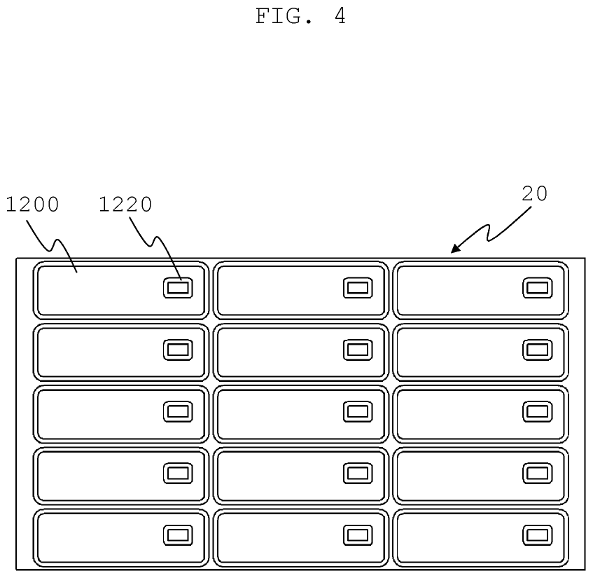

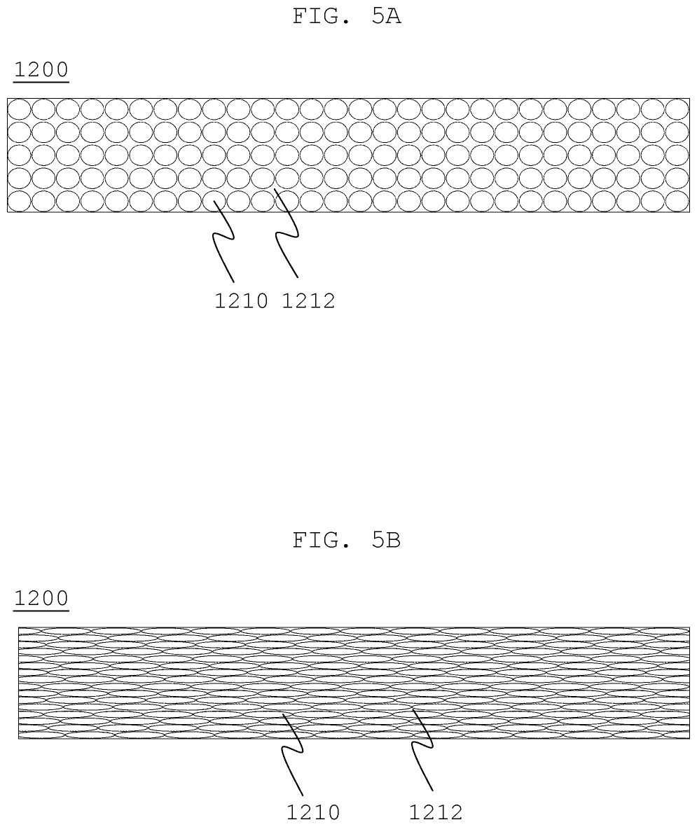

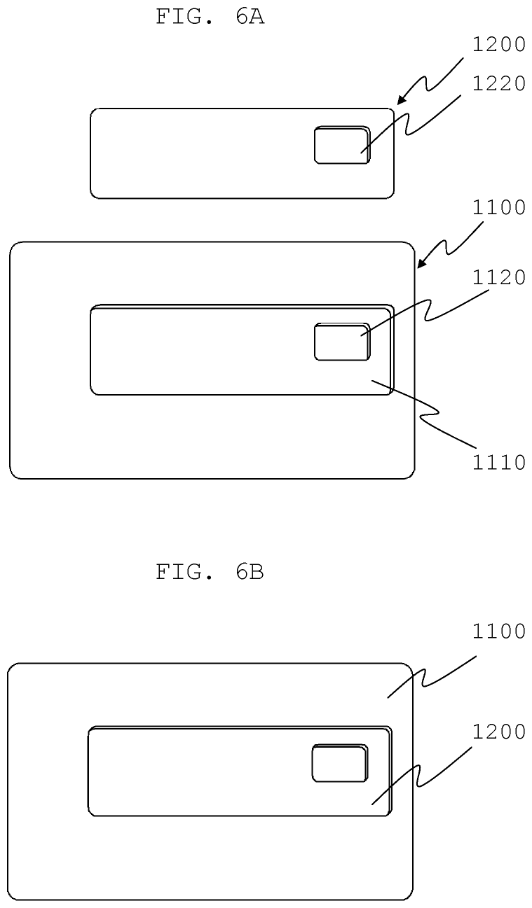

Furthermore, with respect to the recess (1110) of the metal layer (1100), the size of the milling area of the recess (1110), where the shield layer (1200) and the inlay (1500) are to be inserted, should not exceed a length and width of 78 mm and 50 mm respectively for a payment card (1000) with a D1 of 85.6 mm±0.3 mm and a D2 of 53.98 mm±0.3 mm. Having a milling area larger than 78 mm×50 mm may cause failure when attaching the back sheet (1700) and the second adhesive layer (1600) onto the metal layer (1100) after recess (1110) of the metal layer (1100) already received the shield, inlay (1500), IC chip (1300), and first adhesive layer (1500) as shown in FIG. 2. The recess (1110) may have a depth of 0.30 t±0.01 t (t=mm in the depth-direction) (T4) as shown in FIG. 11C. Through a floor of the recess (1110), a hole (1120) of 0.30 t depth (T3) is milled to the permit placement of IC chip (1300) through the hole (1120), this depth due to the IC chip (1300) being approximately 0.4 t in thickness (T1). For normal IC chip (1300) operation, the distance between the second side (1102) of the metal layer (1100) and antenna (1510) of the inlay (1500) is approximately 0.38 t due to the first adhesive layer (1400) being a liquid adhesive; the thickness of a layer of each of the first and second adhesives (1400, 1600) is about 0.025 t (T6, T8), but this thickness is significantly reduced after a press process of a jig (10). After the press process, the antenna (1510) of the inlay (1500) is pushed through the first adhesive layer (1400) and comes substantially close to the shield layer (1200). Therefore, the thickness of the metal layer (1100) and the shield layer (1200) together is about 0.38 t, and the thickness of the first adhesive layer (1400) is not considered. The copper wire of the antenna (1510) is placed at this depth/position of about 0.38 t. Accordingly, with the recess (1110) and the hole (1120) through the recess (1110) milled on the metal layer (1100), the metal layer (1100), as shown in FIGS. 2, 3A-B, and 11C, is about 0.60 t (T2) in thickness at areas of the metal layer (1100) without the recess (1110) (e.g. the borders of the metal layer (1100)) and the metal layer (1100) is about 0.30 t in thickness in areas whereupon the recess (1110) is milled (the hole (1120) of the recess (1110) excepted). The shield layer (1200), as shown in FIGS. 2 and 4, includes a ferromagnetic layer formed by a rolling operation. The ferromagnetic layer includes a binder (1212) and ferromagnetic metal (1210) as shown in FIG. 5A. A binder (1212) is added to the ferromagnetic metal (1210), the ferromagnetic metal (1210) being a combination of compounds which may include iron, chromium, manganese, zinc, or oxidized steel, or a ferromagnetic metal alloy. The rolling operation uses a rolling press device that presses and flattens the ferromagnetic metals (1210) and the binder (1212) into a thinner ferromagnetic metal sheet (20) as shown in FIGS. 4 and 5B, which reduces both the thickness and porosity of the shield layer (1200). Following the rolling operation, the shield layer (1200) may be milled from the ferromagnetic metal sheet (20) as shown in FIG. 4. Also, the hole (1220) of the shield layer (1200), as shown in FIG. 2, may be milled from the ferromagnetic metal sheet (20) shown in FIG. 4. The amount of binder (1212) in the shield layer (1200) ranges from about 8% to about 14%. The thickness of the shield layer (1200) ranges from about 0.06 mm to about 0.10 mm of thickness due to the rolling operation flattening substantially each compound of the ferromagnetic metal (1210) into a coin shape, the result of which is shown in FIGS. 4A and 5B. The reduction in the amount of binding (typically 12% to 18% pre-rolling as shown in FIG. 5A) to as low as about 8% and the reduction in porosity from the flattened metal (e.g. more coined-shaped ferromagnetic metals (1210) of FIG. 5B able to occupy the same volume as the ferromagnetic metals (1210) of FIG. 5A) increases the shield layer's (1200) performance in shielding electromagnetic interference from the metal layer (1100) to the antenna (1510) of the inlay (1500). By using a thin shield layer (1200), the manufacturing process of the payment card (1000) may be made easier.

It is preferable that the finished shield layer (1200) shown in FIGS. 2 and FIG. 6A has a thickness of 0.08 t (T5) as shown in FIG. 11C. Still, for normal RF operation, the thickness of the shield layer (1200) can range from about 0.06 t to 0.10 t. As shown in FIG. 6A, the holes (1120, 1220) of the shield layer (1200) and the metal layer (1100), respectively, are substantially aligned when the shield layer (1200) is placed into the recess (1110) of the metal layer (1100) as shown in FIG. 6B. The holes (1220, 1120) of the shield layer (1200) and the metal layer (1100) are sized to accept the IC chip (1300) respectively.

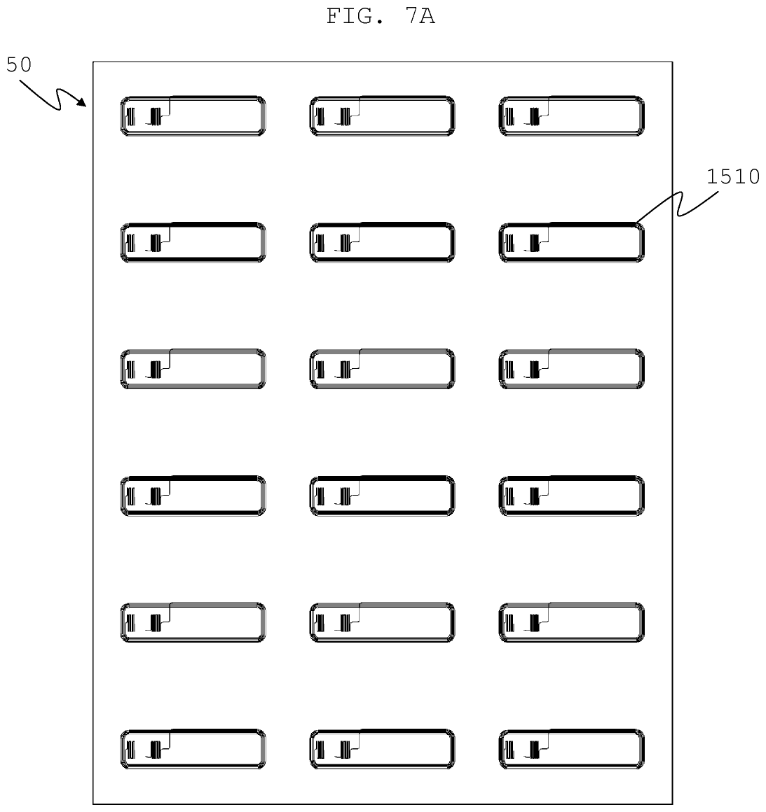

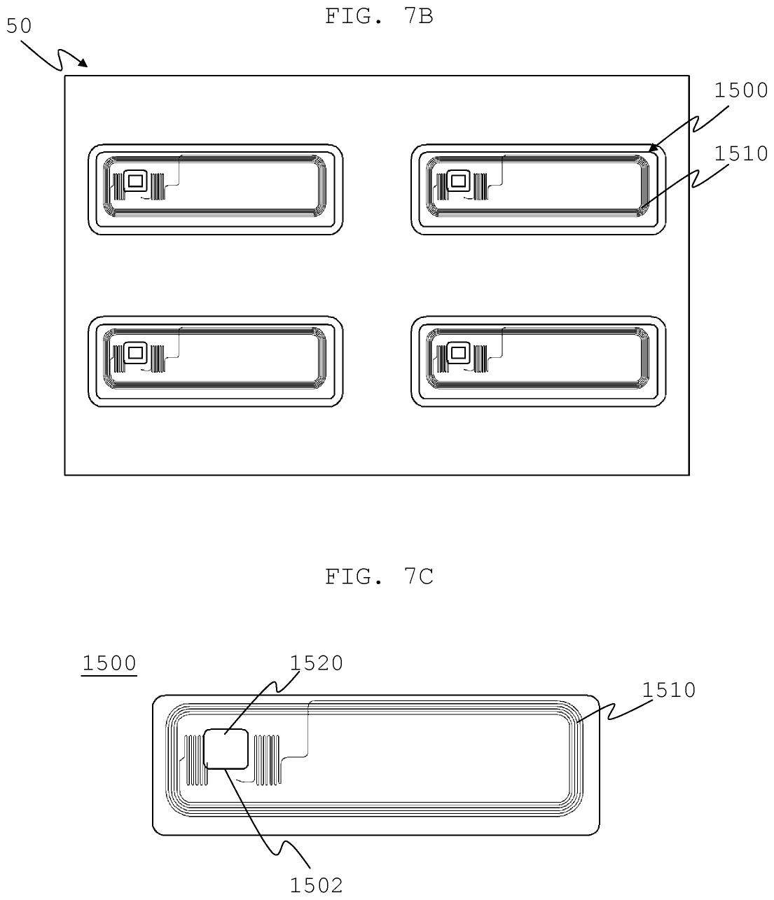

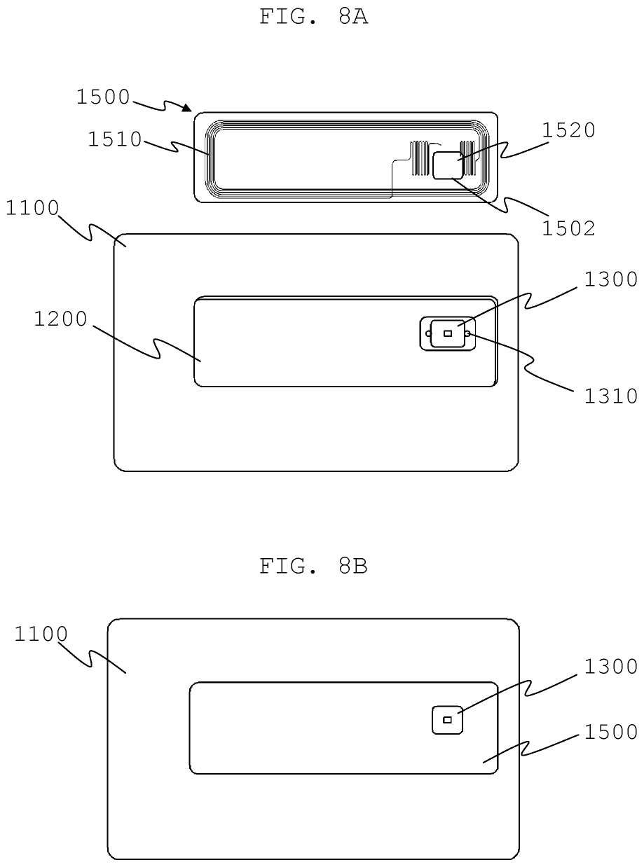

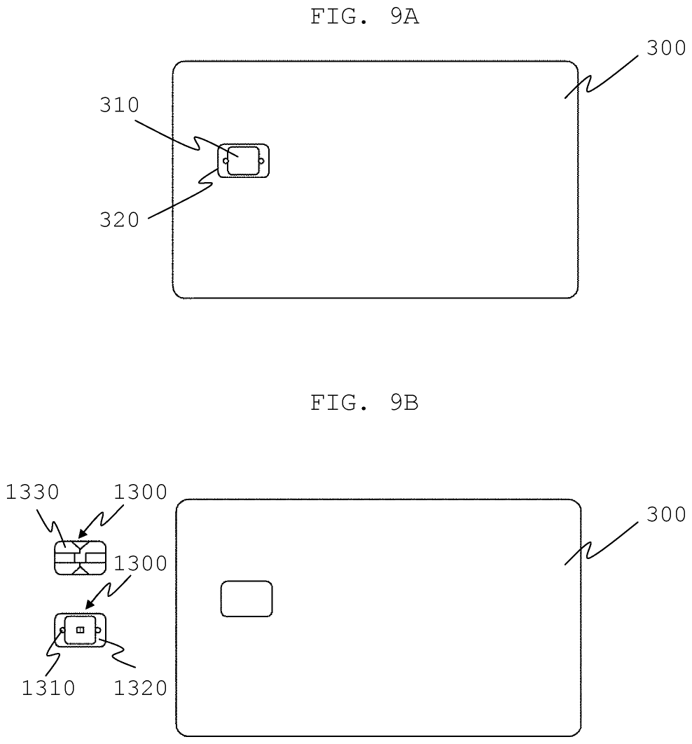

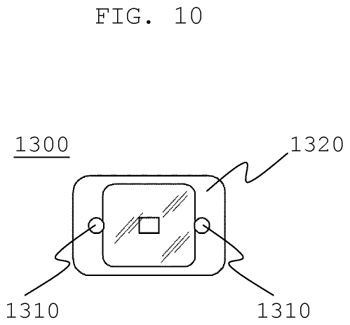

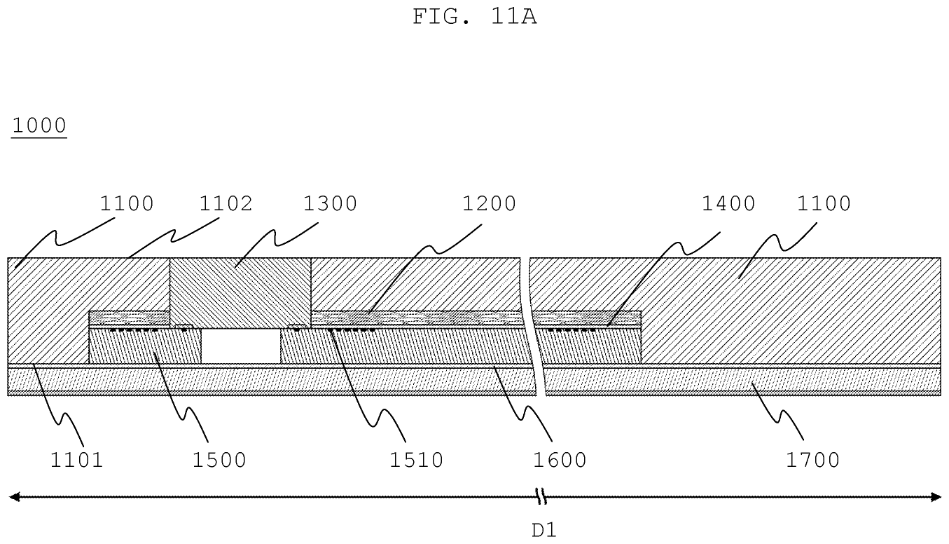

The inlay (1500) used for the payment card (1000) is manufactured from an inlay sheet (50). The inlay (1500) has a thickness of about 0.20 mm±0.01 mm (T7) as shown in FIG. 11C. The inlay (1500) includes an antenna (1510) that contributes about 0.10 mm thickness to the overall thickness of the inlay (1500). Furthermore, the antenna (1510) is formed from a coil of at least three turns, preferably six turns and the coil preferably being copper. As shown in FIGS. 7A, when manufacturing an inlay (1500), a single inlay sheet (50) may include multiple antennas (1510) corresponding to individual inlays (1500). As shown in FIG. 7B, the multiple inlays (1500) and their respective antennas may be milled from the inlay sheet (50). Furthermore, a hole (1520) of the inlay (1500) may be milled as shown in FIGS. 7B and C. Preferably, the size of the inlay hole (1520) as shown will be smaller than the holes (1120, 1220) of the metal layer (1100) and the shield layer (1200) so that the contact area (1310) of the IC chip (1300) may contact the antenna (1510) of the inlay (1500). A first adhesive layer is added to the inlay (1500) via a silk screen on the side of the inlay antenna (1510), and areas of the antenna (1510) for the contact areas (1310) of IC chip (1300) are cleared to remove any adhesive and wire. Preferably, the adhesive is a liquid adhesive having double-sided adhesive properties and is deposited on the inlay at about 0.025 t of thickness. As shown in FIGS. 8A and 8B, the inlay (1500) having a first adhesive layer (1400) applied thereon will be placed upon the shield layer (1200) and IC chip (1300), thus filling the remaining depth of the recess (1110) layer of the metal layer (1100) as shown in FIG. 8B. The inlay (1500) is sized to at least substantially cover the shield layer (1200).

The IC chip (1300) as shown in FIGS. 2, 9B, and 10 features the contact area (1310) that contacts the antenna (1510) of the inlay (1500) as shown FIG. 8B. The IC chip (1300) further includes a hot melt (1320) as well as conductive glue applied to the contact area (1310) (not shown). Preferably, the IC chip (1300) has a thickness of about 0.40 t (T1) as shown in FIG. 11C. Accordingly, the IC chip (1300) is received within the holes (1120, 1220) of the metal layer (1100) and the shield layer (1200) as shown in FIG. 11A when the holes (1120, 1220) of the metal layer (1100) and the shield layer (1200) are substantially aligned with each other. The IC chip (1300) is not received within the hole (1520) of inlay (1500) because an area of the inlay hole (1520) formed by the interior edge (1502) of the inlay (1500) is smaller than an area of the hole (1220) of the shield layer (1200), and subsequently smaller than an area of a first face of the IC chip (1300) corresponding to the surface of the IC chip (1300) where the contact area (1310) is located. A second face of the IC chip (1300), substantially represented by the chip contact (1330), is at least approximately flush with a second side (1102) of the metal layer (1100). For normal IC chip (1300) operation, the distance between the second side (1102) of the metal layer (1100) and the antenna (1510) of the inlay (1500) is about 0.38 t as shown in FIG. 11A due to the first adhesive layer (1400) being a liquid adhesive; the thickness of a layer of each of the first and second adhesives (1400, 1600) is about 0.025 t, but this thickness is significantly reduced after a press process (S800) of a jig (10). After the press process (S800), the antenna (1510) of the inlay (1500) is pushed through the first adhesive layer (1400) and comes substantially close to the shield layer (1200). Therefore, the thickness of the metal layer (1100) and the shield layer (1200) together is about 0.38 t, and the thickness of the first adhesive layer (1400) is not considered. The copper wire of the antenna (1510) is placed at this depth/position of about 0.38 t. Preparation of the IC chip (1300) and its incorporation into the payment card (1000) will be further explained below.

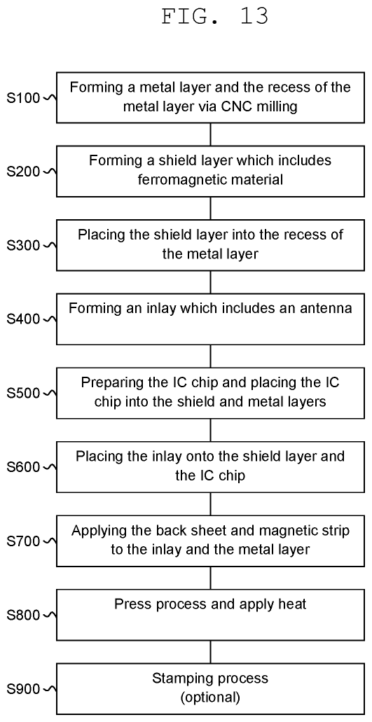

As shown in FIGS. 2 and 11A, a second adhesive layer is added to the side of the inlay (1500) and the metal layer (1100) having already received therein in the recess (1110) of the metal layer (1100) the IC chip (1300), the shield layer (1200), the first adhesive layer, and the inlay (1500). Preferably, the second adhesive layer is added to a side of the inlay (1500) that does not feature the antenna (1510). The second adhesive layer is preferably a liquid adhesive having at least double-sided adhesive properties and is specialized for combining metal and polyvinyl chloride (PVC). A back sheet (1700) as shown in FIGS. 2 and 11A is added to the side of the inlay (1500) having second adhesive layer. As shown in FIG. 12, the back sheet (1700) may be processed from a sheet (70) containing a plurality of back sheets (1700), similar to the processing of multiple shield layers (1200) and inlays (1500) from their respective sheets as shown in FIGS. 4 and 7B. Preferably, the back sheet (1700) includes a carbon whereupon text may be printed. Furthermore, a magnetic strip (1710) may be added on the back sheet (1700) by laser overlay. The carbon sheet and the laser overlay help minimize appearance of cavity marks. Sometime after the printing of the carbon sheet, the back sheet (1700) of the payment card (1000) is laminated and the back sheet (1700), the second adhesive layer, the inlay (1500), the first adhesive layer, and the shield layer (1200) are pressed together with the metal layer (1100) and the IC chip (1300) to produce the payment card (1000).

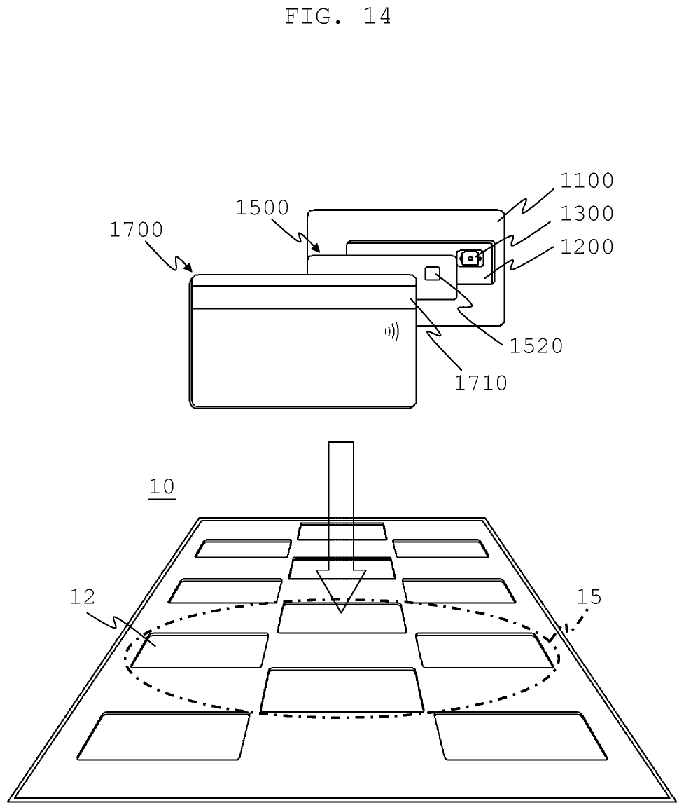

As shown in FIG. 13, a method for manufacturing a payment card (1000), includes the steps of forming a shield layer (1200) (S200) which includes ferromagnetic material (1210); forming an inlay (1500) (S400) wherein the inlay (1500) includes an antenna (1510) and an interior edge (1502) forming a hole (1520); forming a metal layer (1000) (S100) which includes a recess (1110) sized to receive the shield layer (1200); and placing the shield layer (1200) into the recess (1110) of the metal layer (1000) (S300). The shield layer (1200) further includes an opening sized to receive an IC chip (1300). The recess (1110) is formed within a boundary of the metal layer (1100) and on a first side (1101) of the metal layer (1100), wherein the recess (1110) includes an opening through to a second side of the metal layer (1100). The opening of the recess (1110) and the opening of the shield layer (1200) are sized to receive the IC chip (1300) (S500), wherein the IC chip (1300) includes a contact area (1310). The openings (1220, 1120), or holes, of the shield layer (1200) and the metal layer (1100) are substantially aligned with each other when both of them receive the IC chip (1300) (S500).

For the step of forming the shield layer (1200) (S200), the step further includes adding a binder (1212) to the ferromagnetic material (1210) and then forming a ferromagnetic layer by a rolling operation wherein the binder (1212) and the ferromagnetic material (1210), in aggregation, are substantially flattened to reduce porosity as discussed above and shown in FIGS. 4 and FIG. 5B. As discussed above, the ferromagnetic material (1210) includes iron, chromium, manganese, zinc, or oxidized steel, or a ferromagnetic metal alloy including more than one of the aforementioned metals. As shown in FIG. 5B, the ferromagnetic material after the rolling operation resembles an array of coin-shaped ferromagnetic material (1210) and binder (1212). The rolling operation is performed by a rolling press device that provides sufficient pressure or downward force across an entire sheet containing ferromagnetic material (1210) and binder (1212) as shown in FIG. 5A to compress the ferromagnetic material (1210) and binder (1212) such that the ferromagnetic layer includes the ferromagnetic material (1210) compressed down to be coin-shaped as shown in FIG. 5B rather than spherical as shown in FIG. 5A. This rolling operation reduces both the thickness and porosity of the shield layer (1200). Following the rolling operation, the shield layer (1200) may be milled from the ferromagnetic metal sheet (20) as shown in FIG. 4. Also, the hole (1220) of the shield layer (1200), as shown in FIG. 2, may be milled from the ferromagnetic metal sheet (20) shown in FIG. 4. The rolling operation reduces the amount of binder (1212) in the shield layer (1200) from about 12 to 18% as shown in FIG. 5A to 8% to about 14% as shown in FIG. 5B. The thickness of the shield layer (1200) ranges from about 0.06 t to about 0.10 t. The reduction in the amount of binding and the reduction in porosity from the flattened metal allows more coined-shaped ferromagnetic material (1210) of FIG. 5B able to occupy the same volume as the ferromagnetic metals (1210) of FIG. 5A, which increases the shield layer's (1200) performance in shielding electromagnetic interference from the metal layer (1100) to the antenna (1510) of the inlay (1500) and allows the shield layer to adopt thinner profiles.

As shown in FIG. 13, the step of forming the inlay (1500) (S400) further includes adding a first adhesive layer to an inlay sheet (50) via a silk screen, drying the first adhesive layer, and milling to remove unwanted material from the inlay (1500) following the drying step. The area of the inlay (1500) is about the same as or less than the area of the recess (1110) of the metal layer (1100), and an area of the hole (1520) formed by the interior edge (1502) of the inlay (1500) is smaller than an area of the hole (1120) of the metal layer (1100) and smaller than an area of the hole (1220) of the shield layer (1200). As explained earlier, the first adhesive layer (1400) preferably includes the liquid adhesive that is added twice via silk screen and is left to dry for about twelve hours. For proper fitment within the remaining depth of the recess (1110) of the metal layer (1100), the milled area of the inlay (1500) is preferably smaller than area of the recess (1110). For example, the length and width of the milled area of the inlay (1500) are respectively about 0.10 mm smaller than the length and width of the milled area of the recess (1110).

After drying of the first adhesive layer that was added to the inlay (1500), CNC milling is used to cut off only the area of the inlay (1500) that corresponds to the hole (1520) of the inlay (1500). The coil of the antenna (1510) within the IC chip (1300) contact area (1310) location should be scratched to get rid of adhesive from the first adhesive layer and enamel coat that is coating the coil in that location (typically, the coil wire is encased in an enamel coating). After any unwanted adhesive and enamel coating of the coil is removed, the inlay (1500) is ready to be attached to the shield layer (1200) and the IC chip (1300) as shown in FIGS. 8A and 8B, the IC chip (1300) having already placed within the holes (1220, 1120) of the shield layer (1200) and the metal layer (1100). As discussed earlier, the antenna (1510) of the inlay (1500) is about 0.10 t thick and includes at least three turns of the coil, preferably six turns and the coil preferably being copper. For manufacturing the inlay (1500), there are no special upgrades that are required for the device that performs the CNC milling, which means that such devices do not need to suffer significant downtimes due to any specialized or unique retooling.

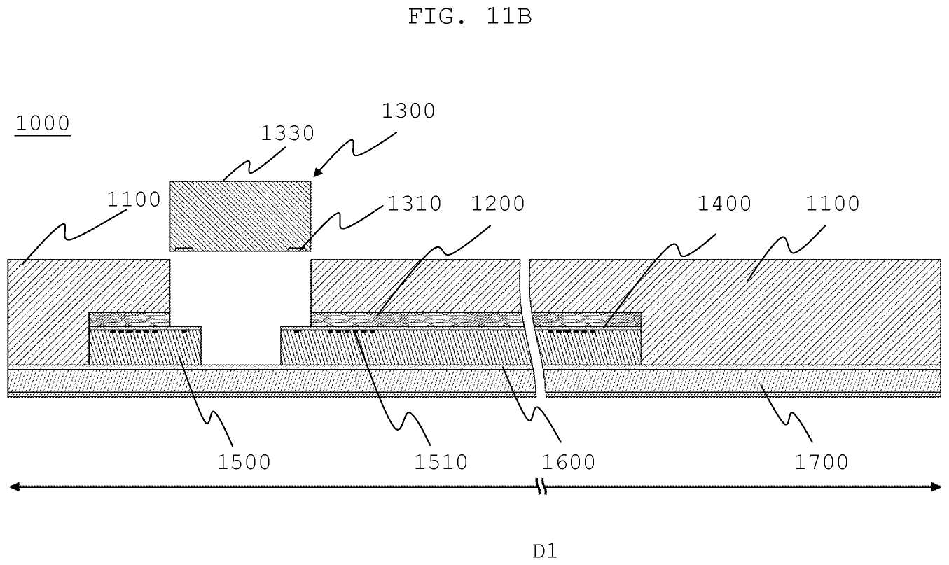

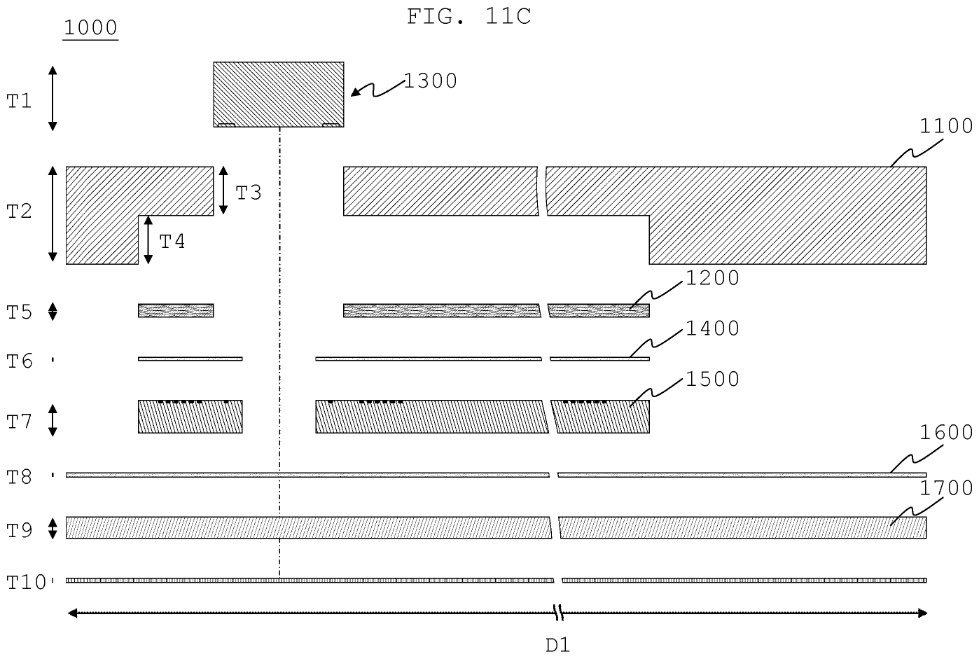

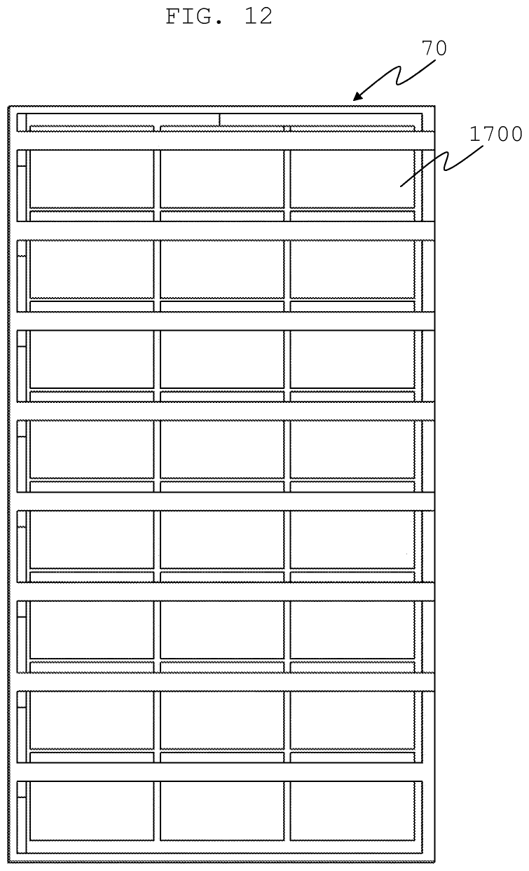

As shown in FIGS. 9A and 9B, preparing the IC chip (1300) for insertion into the metal layer (1100) and the shield layer (1200) (S500) for use with payment includes combining two sheets: a first fabric sheet (300) and a second fabric sheet (310), which may be two different colors (e.g. the first fabric sheet (300) being black; the second fabric (310) sheet being white). Furthermore, hot melt (132) is attached on the IC chip (1300) as shown in FIG. 9B. After combining the first and second fabric sheets (300, 310), laminate the combined sheets (300, 310) via low temperature compression and then perform process punching which includes cutting the sheets (300, 310) according to the D1 and D2 dimensions of the metal layer (1100), as disclosed above, to produce a punched sheet. Low temperature compression involves heating at temperatures that range from about 90° C. to about 110° C. at durations that range from about 20 minutes to about 50 minutes, and then cooling times that range from about 20 minutes to about 40 minutes. The durations for heating and cooling may be longer or shorter for different heating temperatures used. One example of low temperature compression during the lamination of the combined sheets (300, 310) includes heating at about 100° C. for about 30 minutes, and then allowing about 30 minutes for cooling. Another example of low temperature compression includes heating for about 50 minutes at about 90° C., and then cooling for about 20 minutes. Yet another example of low temperature compression includes heating for about 20 minutes at about 110° C., and then cooling for about 40 minutes. Mill an IC chip space (320) on the first fabric sheet (300) of the punched sheet and embed the IC chip (1300) to the IC chip space (320) of the first fabric sheet (300) with the contact area (1310) of the IC chip (1300) directed towards the second fabric sheet (310) that lies underneath the IC chip space (320) milled on the first fabric sheet (300). Following the embedding of the IC chip (1300), the second fabric sheet (310) is detached from the first fabric sheet (300) and the IC chip (1300) embedded in the first fabric sheet (300) then undergoes process chip punching. Prior to insertion of the IC chip (1300) into the holes (1110, 1120) of the metal layer (1100) and the shield layer (1200), conductive glue is added to the contact area (1310) of the IC chip (1300). As shown in the FIG. 10, the contact area (1310) of the IC chip (1300) is on a first face of the IC chip (1300). As shown in FIG. 11A, the distance between a second side (1102) of the metal layer (1100) and the antenna (1510) of the inlay is about 0.38 t for normal IC chip (1300) operation due to the first adhesive layer (1400) being a liquid adhesive; the thickness of a layer of each of the first and second adhesives (1400, 1600) is about 0.025 t, but this thickness is significantly reduced after a press process (S800) of a jig (10). After the press process (S800), the antenna (1510) of the inlay (1500) is pushed through the first adhesive layer (1400) and comes substantially close to the shield layer (1200). Therefore, the thickness of the metal layer (1100) and the shield layer (1200) together is about 0.38 t, and the thickness of the first adhesive layer (1400) is not considered. The copper wire of the antenna (1510) is placed at this depth/position of about 0.38 t.

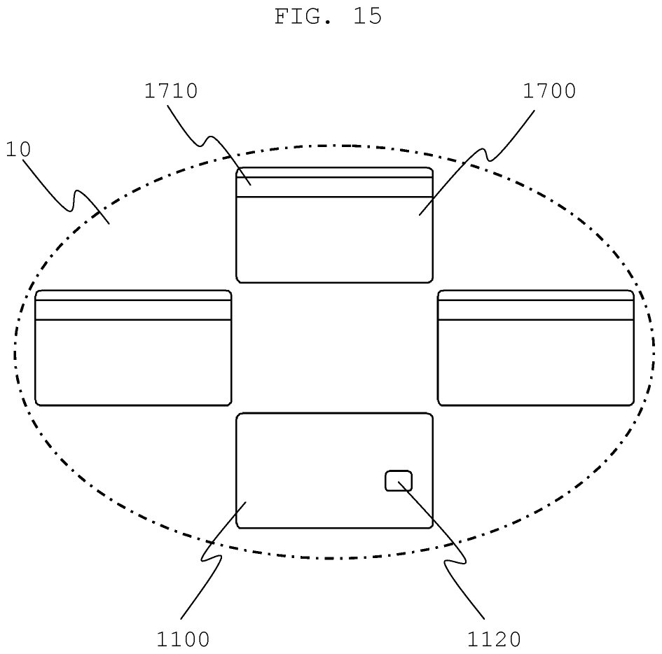

For the forming the back sheet (1700) (S700), a carbon sheet of 0.13 (T9) is combined with a magnetic strip (1710), the latter provided by a laser overlay (having 0.06 t (T10), as shown in FIG. 11C, following process lamination). The use of the carbon sheet and laser overlay helps to minimize appearance of the marks from the recess (1110) of the metal layer (1100) following the heat press in a jig (10) as discussed below. At least one side of the carbon sheet is printed, preferably just one side is printed. This combined sheet, also referred to as the back sheet (1700), then undergoes process lamination. The second adhesive layer is added twice to the back sheet (1700) via silk screen onto the non-printed side of the combined sheet and left to dry for 5 to 6 hours. After the second adhesive layer has been dried, a fabric (preferably white) of about 0.56 t is attached onto the combined sheet and the combined sheet undergoes process punching. After process punching, the fabric is removed and the back sheet (1700) is attached to the metal layer (1100) and the inlay (1500) within the jig (10) as shown in FIGS. 14 and 15.

As shown in FIGS. 14 and 15, the methods of manufacturing a payment card (1000) further includes the steps of placing the metal layer (1100), the shield layer (1200), the IC chip (1300), the inlay (1500), and the back sheet (1700) (together with the first and second adhesive layers) into the jig (10), also referred to as a metal-exclusive jig (10), which includes an opening or a recess (12) sized to receive and hold the these layers as shown in FIG. 15 for pressing and heating thereof (S800). The IC chip (1300) is placed into the openings of the metal layer (1100) and the shield layer (1200) following the step of placing the metal layer into the jig (10) wherein the IC chip (1300) is received in the openings and wherein the contact area (1310) of the IC chip (1300) is directed (i.e. oriented) towards the first side (1101) of the metal layer (1100); and the back sheet (1700) is attached to the metal layer (1100) and the inlay (1500) via the second adhesive layer. While on the metal jig (10), the above components are heated and pressure is applied to the back sheet (1700), the inlay (1500), the IC chip (1300), the shield layer (1200), and the metal layer (1100) received by the metal-exclusive jig (10) to reheat the first and second adhesive layers such that the layers can be pressed and ultimately combined. The temperature used for this heat pressing varies depending on the desired print color. For example, for black color, the applied heat ranges from about 68° C. to about 77° C.; for gold, silver, or other colors, the applied heat ranges from about 68° C. to about 89° C. The duration for heating (no cooling) is about 300 s to minimize marks on the back sheet (1700) shown by the milled recess (1110) of the metal layer (1100) and the press process itself. Since the metal-exclusive jig (10) has a plurality of openings or recesses (12), as shown in FIG. 15 wherein each of the plurality of the openings or recesses (12) is sized to receive and hold the metal layer (1100), multiple payment cards (1000) may be processed at the same time thereby increasing efficiency in the manufacturing of the payment cards (1000).

Optionally, there may be an additional stamping process (S900) performed by a device that attaches signature panels, holograms, ornamental designs and graphics, and the like to the payment card (1000).

While the invention has been shown and described with reference to different embodiments thereof, it will be appreciated by those skilled in the art that variations in form, detail, compositions and operation may be made without departing from the spirit and scope of the invention as defined by the accompanying claims.

What is claimed is:

1. A method for manufacturing a payment card, comprising:
forming a shield layer which includes ferromagnetic material;
forming an inlay wherein the inlay includes an antenna and an interior edge forming a hole;
forming a metal layer which includes a recess sized to receive the shield layer; and
placing the shield layer into the recess of the metal layer,
wherein the shield layer further includes an opening sized to receive an integrated circuit (“IC”) chip,
wherein the recess is formed within a boundary of the metal layer and on a first side of the metal layer,
wherein the recess includes an opening through to a second side of the metal layer,
wherein the opening of the recess and the opening of the shield layer are sized to receive the IC chip, and
wherein the IC chip includes a contact area.

2. The method of claim 1, furthering comprising:
placing the metal layer into a jig which includes an opening or a recess sized to receive and hold the metal layer following the placing of the shield layer step;
aligning the IC chip to the openings of the metal layer and the shield layer following the step of placing the metal layer into the jig wherein the IC chip is received in the openings and wherein the contact area of the IC chip is directed towards the first side of the metal layer;
attaching the inlay onto the shield layer following the aligning step;
attaching a back sheet to the first side of the metal layer; and
heat pressing the back sheet, the inlay, the IC chip, the shield layer, and the metal layer received by the jig.

3. The method of claim 2, wherein the heat pressing step operates from about 68° C. to about 89° C., and
wherein duration of heating is about 300 s.

4. The method of claim 3, wherein the step of forming the inlay further comprises:
adding a first adhesive layer to an inlay sheet via a silk screen;
drying the first adhesive layer following the step of adding the first adhesive layer to the inlay sheet; and
milling, after the drying step, that cuts the inlay from an inlay sheet,
wherein an area of the inlay is less than the area of the recess of the metal layer, and
wherein an area of the hole formed by the interior edge of the inlay is smaller than an area of the hole of the metal layer and smaller than an area of the hole of the shield layer.

5. The method of claim 4, wherein the antenna is about 0.10 t and includes at least three turns of a coil.

6. The method of claim 2, wherein the jig includes a plurality of the openings or recesses wherein each of the plurality of the openings or recesses is sized to receive and hold the metal layer.

7. The method of claim 2, wherein the shield layer is formed having a thickness from about 0.06 t to about 0.10 t, and
wherein the inlay is formed having a thickness of about 0.20 t.

8. The method of claim 1, wherein the step of forming the shield layer further includes adding a binder to the ferromagnetic material and then forming a ferromagnetic layer by a rolling operation wherein the binder and the ferromagnetic material, in aggregation, are substantially flattened to reduce porosity, and
wherein the ferromagnetic material includes iron, chromium, manganese, zinc, or oxidized steel, or a ferromagnetic metal alloy including more than one of the aforementioned metals.

9. The method of claim 8, wherein the binder ranges from about 8% to about 14% of the shield layer.

10. The method of claim 1, wherein the metal layer is about 0.60 t thickness,
wherein the recess has a length from about 50 mm to about 78 mm and a width from about 21 mm to about 50 mm, and
wherein the recess has a depth of about 0.30 t.

11. The method of claim 1, further comprising:
processing the IC chip prior to the aligning step, wherein the processing step includes:
combining first and second fabric sheets which then undergo process lamination at a temperature that ranges from about 90° C. to about 110° C. to produce laminated first and second fabric sheets;
process punching the laminated first and second fabric sheets to produce a punched sheet;
attaching a hot melt on the IC chip;
milling an IC chip space on the punched sheet;
adding the IC chip, having the hot melt, to the IC chip space of the punched sheet;
detaching the lamented second fabric sheet from the punched sheet; and
punching the IC chip from the laminated first fabric sheet;
adding conductive glue onto the contact area of the IC chip.

12. The method of claim 1, wherein a distance between a second side of the metal layer and antenna of the inlay is about 0.38 t,
wherein the metal layer is about 0.60 t in thickness, and
wherein the recess of the metal layer is about 0.30 t in depth.

13. A payment card comprising:
a metal layer which includes a boundary and a recess formed within the boundary;
an inlay which includes an antenna;
a shield layer positioned between the inlay and the metal layer;
an integrated circuit (“IC”) chip including a contact area, wherein the contact area contacts the antenna of the inlay; and
a back sheet constructed to cover the IC chip, the inlay, the shield layer, and the metal layer,
wherein the recess is constructed to receive the shield layer, the IC chip, and the inlay,
wherein the recess and the shield layer include holes sized to receive the IC chip, and
wherein the inlay includes an interior edge forming a hole.

14. The payment card of claim 13, wherein the shield layer comprises a ferromagnetic layer formed by a rolling operation,
wherein ferromagnetic layer includes a binder and ferromagnetic metal,
wherein the ferromagnetic metal includes iron, chromium, manganese, zinc, or oxidized steel, or a ferromagnetic metal alloy including more than one of the aforementioned metals, and
wherein the rolling operation flattens the binder and the ferromagnetic metals to reduce porosity thereof.

15. The payment card of claim 14, wherein the binder ranges from about 8% to about 14% of the shield layer, and
wherein the shield layer ranges from about 0.06 mm to about 0.10 mm of thickness.

16. The payment card of claim 13, wherein the IC chip further includes:
a hot melt; and
conductive glue applied to the contact area,
wherein the IC chip is received in the hole of the metal layer,
wherein the IC chip is received in the hole of the shield layer,
wherein the contact area of the IC chip is directed towards to the antenna,
wherein an area of the hole formed by the interior edge of the inlay is smaller than an area of the hole of the metal layer, and
wherein the area of the hole formed by the interior edge of the inlay is smaller than an area of the hole of the shield layer.

17. The payment card of claim 13, wherein the inlay is produced from an inlay sheet of about 0.20 t thickness,
wherein the antenna includes at least three turns of a coil.

18. The payment card of claim 17, wherein the inlay further includes a first adhesive layer applied on the inlay,
wherein the inlay substantially covers the shield layer, and
wherein the first adhesive layer is at least a double-sided adhesive.

19. The payment card of claim 13, wherein distance between a second side of the metal layer and the antenna of the inlay is about 0.38 t,
wherein the metal layer is about 0.60 t thickness, and
wherein the recess of the metal layer is about 0.30 t depth.

20. The payment card of claim 13, wherein the back sheet includes a carbon sheet and a laser overlay,
wherein the laser overlay includes a magnetic strip, and
wherein the back sheet is laminated.
